(19) United States
(12) Patent Application Publication
(10) Pub. No.: US 2012/0275849 A1
(43) Pub. Date: Nov. 1, 2012

(54) FIXING DEVICE FOR EXPANSION CARD

(75) Inventors: JIA-QI FU, Shenzhen City (CN); HAI-CHEN ZHOU, Shenzhen City (CN); LIN-REN GU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/109,980

(22) Filed: May 17, 2011

(30) Foreign Application Priority Data
Apr. 29, 2011 (CN) 201110110493.0

(51) Int. Cl. H05K 7/00

(52) U.S. Cl. 403/287; 403/331; 403/327

(57) ABSTRACT

A fixing device includes a frame, a positioning member, and a fixing member. A first side end of a expansion card is fixed to a first side of the frame. The positioning member is mounted to a second side of the frame opposite to the first side and capable of sliding toward the first side of the frame. A number of cutouts are longitudinally defined in the second side of the frame. A receiving space is defined in a side of the positioning member for fixing a second end of the expansion card. The fixing member is mounted to the positioning member and selectively fixed to a corresponding cutout of the frame.

### BACKGROUND

1. Technical Field

The present disclosure relates to a device for fixing an expansion card.

2. Description of Related Art

Fixing devices used for fixing expansion cards in computers usually only can fix expansion cards of a particular size, which is less desirable in case that a variety of expansion cards need to be fixed.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a fixing device, together with an expansion card.

FIG. 2 is an assembled, isometric view of FIG. 1.

FIG. 3 is an enlarged view of the circled portion III of FIG. 2.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

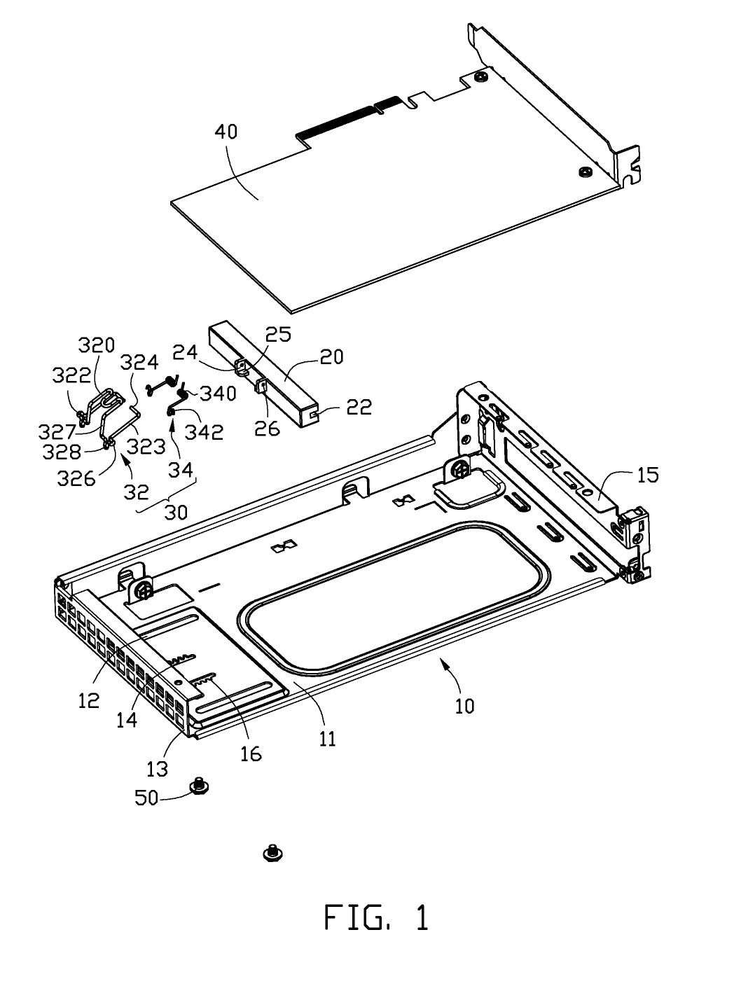

Referring to FIG. 1, an exemplary embodiment of a device for fixing an expansion card 40 includes a frame 10, a positioning member 20, two fasteners 50, and an elastic fixing member 30.

The frame 10 includes a rectangular-shaped board 11, a sidewall 13 substantially perpendicularly extending up from a first side of the board 11, and a fixing portion 15 formed on a second side of the board 11 opposite to the sidewall 13. The board 11 longitudinally defines two first slots 12 and two second slots 14 adjacent to the sidewall 13. The second slots 14 are defined between the first slots 12. A sidewall bounding each second slot 14 and adjacent to a corresponding first slot 12 longitudinally defines a plurality of cutouts 16

The positioning member 20 is substantially bar-shaped, and defines a receiving space 22 in a side of the positioning member 20. The receiving space 22 extends through opposite ends of the positioning member 20. Two tabs 24 substantially perpendicularly extend from a side of the positioning member 20 opposite to the receiving space 22. Each tab 24 defines a through hole 26 parallel to a lengthwise direction of the receiving space 22. A supporting portion 25 perpendicularly extends from a bottom of each tab 24 toward the other tab 24, to be perpendicularly connected to the positioning member 20. The positioning member 20 defines two threaded holes (not shown) in a bottom surface corresponding to the first slots 12.

The fixing member 30 includes a main body 32 and two elastic elements 34.

The main body 32 may be formed by bending a metal wire, and includes a substantially M-shaped central portion 320, and two engaging portions 322 located below opposite sides of the central portion 320.

Each engaging portion 322 includes a pole 323, and a pin 324 extending from a distal end of the pole 323 towards the pole 323 of the other engaging portion 322. A substantially L-shaped connection portion 327 slantingly extends down from each of opposite distal ends of the central portion 320. A substantially U-shaped first blocking portion 328 extends down from a distal end of each connection portion 327. A substantially U-shaped second blocking portion 326 substantially perpendicularly extends from a distal end of the first blocking portion 328, away from the other connection portion 327. The pole 323 substantially extends from a distal end of the second blocking portion 326.

Each elastic element 34 is a torsion spring, and includes a helical portion 340, a first foot (not labeled) extending from a first end of the helical portion 340, and a second foot 342 extending from a second end of the helical portion 340.

Each fastener 50 is, in the embodiment, a screw with a head (not labeled).

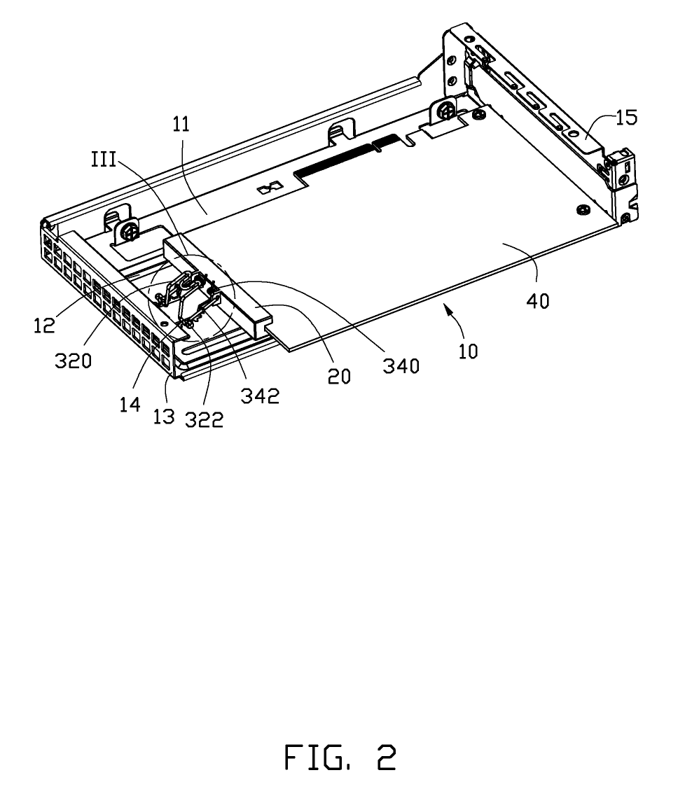

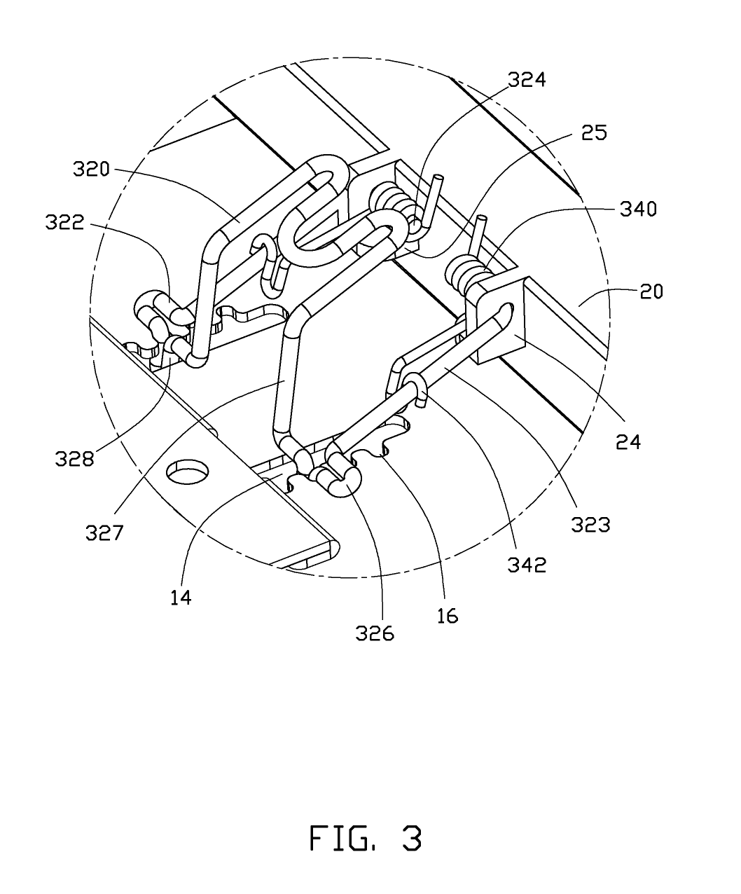

Referring to FIGS. 2 and 3, in assembly, the fasteners 50 extend through the corresponding first slots 12 and engage in the corresponding threaded holes of the positioning member 20. The heads of the fasteners 50 are blocked by a bottom of the frame 10, thereby slidably installing the positioning member 20 to the board 11. The helical portions 340 are supported on the supporting portions of the corresponding tabs 24. The first feet of the elastic elements 34 resist against the side of the positioning member 20 formed with tabs 25. The second feet of the elastic elements 34 fit about the corresponding poles 323. The pins 324 extend through the through holes 26 and engage in the helical portions 340 of the corresponding elastic elements 34.

The connection portions 327 are deformed toward each other, thereby deforming the main body 32. The first blocking portions 328 are selectively inserted into two of the cutouts 16 of the corresponding second slots 14. At this time, the second blocking portions 326 resist against a top of the board 11. The second feet 342 press the corresponding poles 323 toward the board 11, for preventing the first blocking portions 328 from disengaging from the corresponding cutouts 16.

In use, a first side end of the expansion card 40 is fixed to the fixing portion 15. The connection portions 327 are pressed toward each other to disengage the first blocking portions 328 from the corresponding cutouts 16. The positioning member 20 is slid toward a second side end of expansion card 40, until the second side end of the expansion card 40 is received in the receiving space 22. The first blocking portions 328 are then engaged in two corresponding cutouts 16, to fix the expansion card 40 to the frame 10. Each first blocking portion 328 can be selectively engaged in one of the cutouts of a corresponding second slot 14, to fit the size of the expansion card 40.

It is believed that the present embodiments and their advantages will be understood from the foregoing description, and they will be apparent that various changes may be made thereto without departing from the spirit and scope of the description or sacrificing all of their material advantages, the examples hereinbefore described merely being exemplary embodiment.

What is claimed is:

1. A fixing device for fixing an expansion card, the fixing device comprising:
a frame comprising a first side, a second side of the frame opposite to the first side operable to fix a first side end of the expansion card, a plurality of cutouts defined adjacent to the first side of the frame and arranged in a direction from the first side to the second side;
a positioning member slidably mounted to the first side of the frame, the positioning member defining a receiving space in a side facing the second side of the frame, to accommodate a second side end of the expansion card opposite to the first side end; and
a fixing member mounted to the positioning member and selectively engaging with at least one of the plurality of cutouts to fix the positioning member.

2. The fixing device of claim 1, wherein the frame comprises a board defining two first slots and two second slots, adjacent to the first side and extending in a direction from then first side to the second side, the plurality of cutouts comprises two rows of cutouts formed in the two second slots, respectively, each row of cutouts is defined in a sidewall bounding a corresponding one of the two second slots, the fixing member comprises a main body, the main body comprises two engaging portions each comprising a first end and the second end, the first ends of the engaging portions are mounted to the positioning member, the second ends of the engaging portions are selectively engaged in two of the two rows of cutouts with one from each row.

3. The fixing device of claim 2, wherein two tabs protrude from a side of the positioning member away from the receiving space, each tab defines a through hole, each engaging portion of the fixing member comprises a pole, a pin extends from a distal end of each pole and extends through the through hole of a corresponding tab.

4. The fixing device of claim 3, wherein a first blocking portion is formed on the other end of each pole opposite to the pin to engage in a corresponding cutout of the frame.

5. The fixing device of claim 4, wherein a second blocking portion is formed adjacent to the corresponding first blocking portion of each pole and resists against the board in response to the first blocking portion engaging in a corresponding cutout.

6. The fixing device of claim 4, wherein the main body of the fixing member comprises an elastic central portion, the engaging portions are positioned at opposite sides of the central portion, a connection portion slantingly connected between a corresponding distal end of the central portion and a distal end of a corresponding first blocking portion.

7. The fixing device of claim 5, wherein the fixing member further comprises two torsion springs, each torsion springs comprises a helical portion mounted to the side of the positioning member formed with two tabs, a first foot of the torsion spring resists against the positioning member, a second foot of the torsion spring fixed to the pole of a corresponding engaging portion.

8. A fixing device for fixing an expansion card, the fixing device comprising:
a frame comprising a first side, a second side of the frame opposite to the first side operable to fix a first side end of the expansion card, at least one row of cutouts defined adjacent to the first side of the frame and arranged in a direction from the first side to the second side;
a positioning member slidably mounted to the first side of the frame, the positioning member defining a receiving space to accommodate a second side end of the expansion card, the movement direction of the positioning member parallel to a lengthwise direction of the frame; and
a fixing member mounted to the positioning member and selectively fixed to one of each of the at least one row of cutouts to fix the positioning member.

9. The fixing device of claim 8, wherein the fixing member comprises a main body and a torsion spring, the main body is selectively engaged in one of the cutouts, the torsion spring is supported on the positioning member, a first foot of the torsion spring resists against the positioning member, a second foot of the torsion spring is fixed to the main body.

10. The fixing device of claim 9, wherein the main body is formed by bending a metal wire.

11. The fixing device of claim 10, wherein the main body comprises a substantially cantilevered M-shaped central portion, two slanted connection portions extending down from opposite ends of the central portion, two first blocking portions extending from distal ends of the connection portions opposite to the central portion, and two second blocking portions extending from the first blocking portions, the frame defines two rows of cutouts, the first blocking portions are selectively engaged in two of the two rows of cutouts, the second blocking portions resist against the frame.

12. The fixing device of claim 11, wherein the main body further comprises two poles extending from the second blocking portions, two pins extend from distal ends of the poles to engage in the positioning member and the torsion spring.
